(19) United States
(12) Patent Application Publication
(10) Pub. No.: US 2015/0012241 A1
(43) Pub. Date: Jan. 8, 2015

(54) ADAPTIVE AUTOMATIC GAIN CONTROL APPARATUS AND METHOD FOR INERTIAL SENSOR

(71) Applicant: SAMSUNG ELECTRO-MECHANICS CO., LTD., Suwon (KR)

(72) Inventors: Byoung Won Hwang, Suwon (KR); Kyung Rin Kim, Suwon (KR); Chang Hyun Kim, Suwon (KR)

(73) Assignee: SAMSUNG ELECTRO-MECHANICS CO., LTD., Suwon (KR)

(21) Appl. No.: 14/049,496

(22) Filed: Oct. 9, 2013

(30) Foreign Application Priority Data
Jul. 8, 2013 (KR) 10-2013-0079870

(51) Int. Cl. B81B 7/00; G01P 3/44

(52) U.S. Cl. CPC B81B 7/008; G01P 3/44; B81B 2201/0228; B81B 2207/01
USPC 702/147

(57) ABSTRACT

Disclosed herein are an adaptive automatic gain control apparatus and method for an inertial sensor. The adaptive automatic gain control apparatus for an inertial sensor, includes: a displacement measuring unit measuring and outputting a driving displacement of the inertial sensor; and a controlling unit driving the inertial sensor using an initial driving signal and then resetting a driving signal while changing a margin value using the driving displacement measured by the displacement measuring unit, thereby driving the inertial sensor.

### CROSS REFERENCE TO RELATED APPLICATION

This application claims the benefit of Korean Patent Application No. 10-2013-0079870, filed on Jul. 8, 2013, entitled “Adaptive Automatic Gain Control Apparatus for Inertial Sensor and Method Thereof”, which is hereby incorporated by reference in its entirety into this application.

### BACKGROUND OF THE INVENTION

1. Technical Field

The present invention relates to an adaptive automatic gain control apparatus and method for an inertial sensor.

2. Description of the Related Art

An inertial sensor generally includes a mass resonating in a micro electro-mechanical system (MEMS) structure. When an angular velocity input is applied from the outside in a state in which the mass resonates, Coriolis force is generated in a direction perpendicular to a direction in which the mass resonates and rotates and the generated signal is electrically processed and output.

Therefore, even though the same angular velocity signal is applied to the inertial sensor, large Coriolis force is generated when the resonance becomes large and small Coriolis force is generated when the resonance becomes small, such that an output value is changed according to a resonance state of the mass.

That is, a degree of stability of the resonance of the mass of the inertial sensor is one of the very important factors in determining performance of the inertial sensor.

However, in the MEMS structure of the inertial sensor, due to an external environment change such as temperature, humidity, etc., an internal change, or the like, such as deterioration of the MEMS structure itself that may be generated over time, a problem that the mass is not maintained to constantly resonate at an initially set target value, but resonates at an amplitude that is out of the target value.

Therefore, in order to solve this problem, an automatic gain control (AGC) apparatus is generally used.

The automatic gain control apparatus uses a scheme of automatically controlling a resonance gain of the mass so that the mass of the inertial sensor may be always driven at an initial target value set in order to drive the inertial sensor.

Generally, in order to perform an automatic gain control, a gain applying scheme of judging a resonance state of the mass that is currently resonating and judging a difference between the judged resonance state and a resonance target value to correct the resonance of the mass by the difference is used.

To this end, in a scheme according to the prior art, in performing the automatic gain control, a target value has been set and a magnitude of a driving signal (V(t)) has been controlled by a proportional integral differential (PID) control so that a driving displacement (t) of the MEMS structure of the inertial sensor is converged on the set target value.

In this case, a margin value is set so that oscillation is not generated in the vicinity of the target value. The margin value has an effect on accuracy and a driving deviation (e(t)) of the automatic gain control.

In order to increase the accuracy of the automatic gain control and decrease the driving deviation of the automatic gain control, it is advantageous to set the margin value to be small.

However, when the margin value is set to be excessively small, a time required to arrive at the target value becomes excessively long, such that a desired response speed in the inertial sensor may not be obtained.

On the other hand, when the margin value is set to be excessively large, the response speed is increased; however, the accuracy of the automatic gain control is decreased and the driving deviation is increased.

### PRIOR ART DOCUMENT

### Patent Document

(Patent Document 1) Korean Patent Laid-Open Publication No. 2007-0054469
(Patent Document 2) Korean Patent Laid-Open Publication No. 2008-0090340
(Patent Document 3) Korean Patent Laid-Open Publication No. 2011-0126546

### SUMMARY OF THE INVENTION

The present invention has been made in an effort to provide an adaptive automatic gain control apparatus and method for an inertial sensor capable of minimizing a driving deviation by controlling a margin value so as to be variable according to a situation rather than being fixed.

Further, the present invention has been made in an effort to provide an adaptive automatic gain control apparatus and method for an inertial sensor capable of improving a response speed by setting a margin value using observed values of a driving displacement gathered for a predetermined time after a response time elapses.

According to a preferred embodiment of the present invention, there is provided an adaptive automatic gain control apparatus for an inertial sensor, including: a displacement measuring unit measuring and outputting a driving displacement of the inertial sensor; and a controlling unit driving the inertial sensor using an initial driving signal and then resetting a driving signal while changing a margin value using the driving displacement measured by the displacement measuring unit, thereby driving the inertial sensor.

The adaptive automatic gain control apparatus for an inertial sensor may further include a low pass filter filtering noise from the driving displacement measured by the displacement measuring unit to provide the driving displacement from which the noise is filtered to the controlling unit.

The controlling unit may drive the inertial sensor using the initial driving signal, calculate a driving deviation by subtracting the driving displacement measured by the displacement measuring unit from a driving displacement target value after a predetermined time elapses, and reset the driving signal while decreasing the margin value when the calculated driving deviation is in the range of an initial maximum margin value, thereby driving the inertial sensor.

The controlling unit may drive the inertial sensor using the reset driving signal and reset the driving signal while decreasing the margin value when the driving deviation is in the range of the previous margin value after a predetermined time elapses, thereby driving the inertial sensor.

The controlling unit may drive the inertial sensor using the reset driving signal and reset the driving signal while increasing the margin value when the driving deviation is out of the range of the previous margin value after a predetermined time elapses, thereby driving the inertial sensor.

The controlling unit may maintain the driving signal when the driving deviation again enters the range of the margin value.

The controlling unit may include: a timer outputting a time-out signal at a predetermined time interval; a margin calculator subtracting or adding an increase or decrease value from or to the previous margin value to output an adjusted margin value; and a proportional integral derivative (PID) controller drives the inertial sensor using the initial driving signal, calculates the driving deviation by subtracting the driving displacement measured by the displacement measuring unit from the driving displacement target value when the time-out signal is output from the timer, requests the margin calculator to decrease the margin value when the calculated driving deviation is in the range of the initial maximum margin value, and receives the decreased margin value to reset the driving signal, thereby driving the inertial sensor.

The PID controller may drive the inertial sensor using the reset driving signal, calculate the to driving deviation by subtracting the driving displacement measured by the displacement measuring unit from the driving displacement target value when the time-out signal is output from the timer, request the margin calculator to decrease the margin value when the driving deviation is in the range of the previous margin value, and receive the decreased margin value to reset the driving signal, thereby driving the inertial sensor.

The controlling unit may further include a stabilizer having a decrease flag, maintained in an enabled state when the driving deviation is in the range of the previous margin value, and maintained in a disabled state when the driving deviation is out of the range of the previous margin value, wherein the PID controller drives the inertial sensor using the reset driving signal, calculates the driving deviation by subtracting the driving displacement measured by the displacement measuring unit from the driving displacement target value when the time-out signal is output from the timer, changes a state of the stabilizer into the disabled state and requests the margin calculator to increase the margin value when the driving deviation is out of the range of the margin value, and receives the increased margin value to reset the driving signal, thereby driving the inertial sensor.

The PID controller may calculate the driving deviation by subtracting the driving displacement measured by the displacement measuring unit from the driving displacement target value when the time-out signal is output from the timer and request the margin calculator to decrease the margin value when the driving deviation again enters the range of the margin value, the margin calculator may confirm a state of the stabilizer and output the previous margin value to the HD controller when the stabilizer is in the disabled state, and the HD controller may maintain the driving signal when the previous margin value is output from the margin calculator.

The controlling unit may drive the inertial sensor using the initial driving signal, gather amplitudes of the driving displacement in each of a plurality of periods measured by the displacement measuring unit as observed values to calculate a parameter after a predetermined time elapses, set the margin value using the parameter, calculate a driving deviation by subtracting the driving displacement measured by the displacement measuring unit from a driving displacement target value, and reset the driving signal when the calculated driving deviation is out of the range of the set margin value, thereby driving the inertial sensor.

The controlling unit may drive the inertial sensor using the reset driving signal, gather the amplitudes of the driving displacement in each of the plurality of periods measured by the displacement measuring unit as the observed values to calculate the parameter after a predetermined time elapses, set the margin value using the parameter, calculate the driving deviation by subtracting the driving displacement measured by the displacement measuring unit from the driving displacement target value, and reset the driving signal when the calculated driving deviation is out of the range of the set margin value, thereby driving the inertial sensor.

The controlling unit may drive the inertial sensor using the reset driving signal, gather the amplitudes of the driving displacement in each of the plurality of periods measured by the displacement measuring unit as the observed values to calculate the parameter after the predetermined time elapses, set the margin value using the parameter, calculate the driving deviation by subtracting the driving displacement measured by the displacement measuring unit from the driving displacement target value, and maintain the driving signal when the calculated driving deviation is in the range of the set margin value, thereby driving the inertial sensor.

The parameter may be at least one of an average of the observed values, a deviation of the observed values, a deviation maximum value of the observed values, a variance of the observed values, and a standard deviation of the observed values.

The controlling unit may include: a gatherer gathering the amplitudes of the driving displacement in each of the plurality of periods measured by the displacement measuring unit as the observed values; a parameter calculator calculating the parameter using the observed values gathered by the gatherer; a margin calculator setting the margin value using the parameter calculated by the parameter calculator; and a PID controller drives the inertial sensor using the initial driving signal, sets the margin value using the gatherer, the parameter calculator, and the margin calculator, calculates the driving deviation by subtracting the driving displacement measured by the displacement measuring unit from the driving displacement target value, and resets the driving signal when the calculated driving deviation is out of the range of the set margin value, thereby driving the inertial sensor.

The PID controller may drive the inertial sensor using the reset driving signal, set the margin value using the gatherer, the parameter calculator, and the margin calculator, calculate the driving deviation by subtracting the driving displacement measured by the displacement measuring unit from the driving displacement target value, and reset the driving signal when the calculated driving deviation is out of the range of the set margin value, thereby driving the inertial sensor.

The PID controller may drive the inertial sensor using the reset driving signal, set the margin value using the gatherer, the parameter calculator, and the margin calculator, calculate the driving deviation by subtracting the driving displacement measured by the displacement measuring unit from the driving displacement target value, and maintain the driving signal when the calculated driving deviation is in the range of the set margin value, thereby driving the inertial sensor.

According to another preferred embodiment of the present invention, there is provided an adaptive automatic gain control method for an inertial sensor, including: (A) driving, by a controlling unit, the inertial sensor using an initial driving signal; (B) outputting, by a displacement measuring unit, measuring and outputting a driving displacement of the inertial sensor after a predetermined time elapses; and (C) resetting, by the controlling unit, the driving signal while changing a margin value using the driving displacement measured by the displacement measuring unit, thereby driving the inertial sensor.

The adaptive automatic gain control method for an inertial sensor may further include, after the step (B), (D) filtering, by a low pass filter, noise from the driving displacement measured by the displacement measuring unit to provide the driving displacement from which the noise is filtered to the controlling unit.

The step (C) may include: (C-1) calculating, by the controlling unit, a driving deviation by subtracting the driving displacement measured by the displacement measuring unit from a driving displacement target value; and (C-2) resetting, by the controlling unit, the driving signal while decreasing the margin value when the calculated driving deviation is in the range of an initial maximum margin value, thereby driving the inertial sensor.

The adaptive automatic gain control method for an inertial sensor may further include: (E) driving, by the controlling unit, the inertial sensor using the reset driving signal; (F) measuring and outputting, by the displacement measuring unit, the driving displacement of the inertial sensor after the predetermined time elapses; (G) calculating, by the controlling unit, the driving deviation by subtracting the driving displacement measured by the displacement measuring unit from the driving displacement target value; and (H) resetting, by the controlling unit, the driving signal while decreasing the margin value when the calculated driving deviation is in the range of the previous margin value, thereby driving the inertial sensor.

The adaptive automatic gain control method for an inertial sensor may further include (I) resetting the driving signal while increasing the margin value when the driving deviation calculated in the step (G) is out of the range of the previous margin value, thereby driving the inertial sensor.

The adaptive automatic gain control method for an inertial sensor may further include: (J) driving, by the controlling unit, the inertial sensor using the reset driving signal; (K) measuring and outputting, by the displacement measuring unit, the driving displacement of the inertial sensor after the predetermined time elapses; (L) calculating, by the controlling unit, the driving deviation by subtracting the driving displacement measured by the displacement measuring unit from the driving displacement target value; and (M) maintaining, by the controlling unit, the driving signal when the driving deviation again enters the range of the margin value, thereby driving the inertial sensor.

The step (C) may include: (C-1) gathering, by the controlling unit, amplitudes of the driving displacement in each of a plurality of periods measured by the displacement measuring unit as observed values to calculate a parameter and setting the margin value using the parameter; and (C-2) calculating, by the controlling unit, a driving deviation by subtracting the driving displacement measured by the displacement measuring unit from a driving displacement target value, and resetting the driving signal when the calculated driving deviation is out of the range of the set margin value, thereby driving the inertial sensor.

The adaptive automatic gain control method for an inertial sensor may further include: (N) driving, by the controlling unit, the inertial sensor using the reset driving signal; (O) measuring and outputting, by the displacement measuring unit, the driving displacement after a predetermined time elapses; (P) gathering, by the controlling unit, the amplitudes of the driving displacement in each of the plurality of periods measured by the displacement measuring unit as the observed values to calculate the parameter and setting the margin value using the parameter; (Q) calculating, by the controlling unit, the driving deviation by subtracting the driving displacement measured by the displacement measuring unit from the driving displacement target value; and (R) resetting, by the controlling unit, the driving signal when the calculated driving deviation is out of the range of the set to margin value, thereby driving the inertial sensor.

The adaptive automatic gain control method for an inertial sensor may further include (S) maintaining, by the controlling unit, the driving signal when the driving deviation calculated in the step (Q) is in the range of the set margin value, thereby driving the inertial sensor.

The parameter may be at least one of an average of the observed values, a deviation of the observed values, a deviation maximum value of the observed values, a variance of the observed values, and a standard deviation of the observed values.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a configuration diagram of an adaptive automatic gain control apparatus for an inertial sensor according to a preferred embodiment of the present invention;

FIG. 2 is a detailed driving diagram of a controlling unit of FIG. 1 according to a first preferred embodiment of the present invention;

FIG. 3 is a flow chart of an automatic gain control method according to the first preferred embodiment of the present invention;

FIG. 4 is a diagram showing a driving displacement graph used in the preferred embodiment of the present invention;

FIG. 5 is a configuration diagram of a controlling unit of FIG. 1 according to a second preferred embodiment of the present invention; and

FIG. 6 is a flow chart of an automatic gain control method according to the second preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

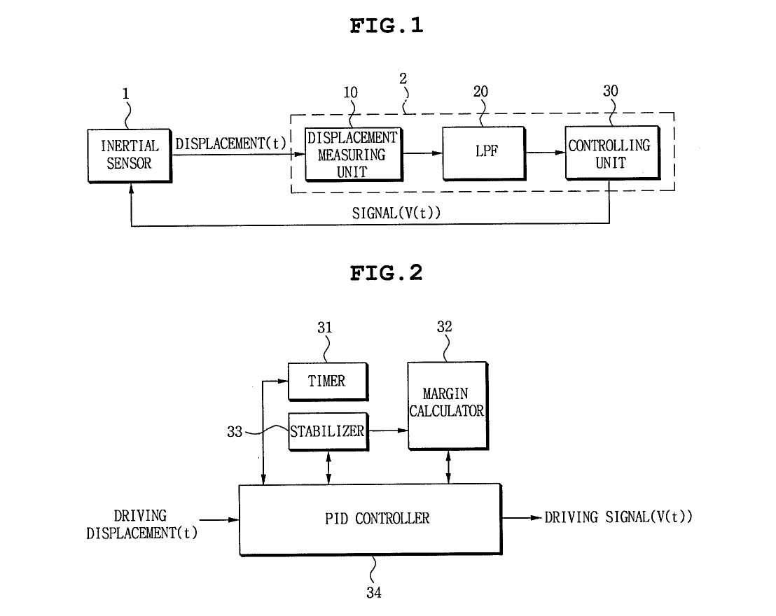

FIG. 1 is a configuration diagram of an adaptive automatic gain control apparatus for an inertial sensor according to a preferred embodiment of the present invention.

Referring to FIG. 1, the adaptive automatic gain control apparatus 2 for an inertial sensor 1 is configured to include a displacement measuring unit 10, a low pass filter 20, and a controlling unit 30.

In this configuration, the inertial sensor 1 may be a gyro sensor.

In addition, the displacement measuring unit 10 measures a driving displacement of a mass that is resonating in the inertial sensor 1.

An automatic gain control makes the driving displacement constant regardless of an external environment change and deterioration of characteristics. Therefore, the driving displacement is used as an input value of the controlling unit 30.

Next, the low pass filter 20 filters a noise component of a mass, which is a structure of the inertial sensor, and a noise component of a circuit that are included in the driving displacement measured by the displacement measuring unit 10 and outputs data from which the noise components are filtered.

In order to filter the noise component as described above, the low pass filter 20 needs to have a cutoff frequency smaller than a resonant frequency of the mass, which is the structure of the inertial sensor, and close to a direct current (DC) voltage.

Pure driving displacement data from which the noise is filtered by the low pass filter 20 are input to the controlling unit 30.

Meanwhile, the controlling unit 30 performs an automatic gain control while varying a margin value rather than using a fixed margin value.

To this end, the controlling unit 30 applies an initial driving signal to the inertial sensor at an initial margin maximum value (margin_max) and receives the driving displacement from the displacement measuring unit 10.

In addition, the controlling unit 30 subtracts the driving displacement from a target value to calculate a driving deviation and decreases a margin value when the calculated driving deviation is in the range of the margin value, thereby decreasing a magnitude of the driving signal.

The controlling unit 30 continuously performs the automatic gain control using the driving signal of which the magnitude is decreased and then receives the driving displacement from the displacement measuring unit 10.

In addition, the controlling unit 30 again subtracts the driving displacement from the target value to calculate a driving deviation and decreases a margin value when the calculated driving deviation is in the range of the margin value, thereby decreasing a magnitude of the driving signal and repeats the above-mentioned process.

Unlike this, the controlling unit 30 increases the margin value when the calculated driving deviation is out of the margin value, thereby increasing a magnitude of the driving signal and repeats the above-mentioned process until the calculated driving deviation arrives at the range of the margin value.

More specifically, the controlling unit 30 applies the initial driving signal to the inertial sensor at the initial margin maximum value (margin_max) and receives the driving displacement from the displacement measuring unit 10.

In addition, the controlling unit 30 subtracts the driving displacement from the target value when the automatic gain control operation as described above is stably continued for a predetermined time, thereby calculating the driving deviation, decreases the margin value from the initial margin maximum value by an increase or decrease value (Δ) when the calculated driving deviation is in the range of the initial margin maximum value, and again continues the automatic gain control operation. Here, as the increase or decrease value (Δ), any value in the range of 5 to 60% of the initial margin maximum value, preferably, any one value in the range of 10 to 30% of the initial margin maximum value may be used. In this case, the controlling unit 30 also decreases the magnitude of the driving signal to a predetermined magnitude.

In addition, the controlling unit 30 subtracts the driving displacement from the target value when the automatic gain control operation as described above is stably continued for a predetermined time, thereby again calculating the driving deviation, decreases the margin value from the previous margin value by an increase or decrease value (Δ) when the calculated driving deviation is in the range of the previous margin value, and again continues the automatic gain control operation. Even in this case, the controlling unit 30 also decreases the magnitude of the driving signal to a predetermined magnitude.

When the controlling unit 30 repeats the automatic gain control operation in the above-mentioned scheme, the margin value is decreased, such that the driving deviation of the automatic gain control is minimized.

The controlling unit 30 repeats the above-mentioned operation until the driving deviation obtained by subtracting the driving displacement from the target value becomes larger than the margin value.

That is, when the controlling unit 30 continuously decreases the margin value, the case in which the driving deviation is not in the range of the margin value, but is out of the margin value at any point in time, occurs.

Then, the controlling unit 30 adds the increase or decrease value (Δ) to the previous margin value when the driving deviation becomes larger than the margin value, thereby increasing the margin value, and then continues again the automatic gain control operation. In this case, the controlling unit 30 increases the magnitude of the driving signal to a predetermined magnitude.

When the controlling unit 30 repeats the automatic gain control operation in the above-mentioned scheme, the margin value is increased. Therefore, the driving deviation is again included in the range of the margin value.

In this case, when a stabilizing apparatus is not present, the controlling unit 30 oscillates while repeating an operation (Margin(t)−Δ) of decreasing the margin value and an operation (Margin(t)+Δ) of increasing the margin value.

In order to solve this problem, the controlling unit 30 includes a decrease flag (decrease_flag) and disables the decrease flag, that is, makes the decrease flag (decrease_flag) 0, in the case in which it is judged that the automatic gain control operation is stably performed when the margin value is further increased, thereby allowing the margin value not to be decreased.

As a result, when a stabilizing apparatus is not present, the controlling unit 30 does not repeat the operation (Margin(t)−Δ) of decreasing the margin value and the operation (Margin(t)+Δ) of increasing the margin value, such that it does not oscillate.

Meanwhile, a detailed configuration of the controlling unit 30 performing the above-mentioned operation is shown in FIG. 2, which will be described below in detail.

FIG. 2 is a detailed driving diagram of a controlling unit of FIG. 1 according to a first preferred embodiment of the present invention.

Referring to FIG. 2, the controlling unit of FIG. 1 includes a timer 31, a margin operator 32, a stabiliser 33, and a proportional integral derivative (PID) controller 34.

The timer 31 starts to be operated by a control of the PID controller 34 and outputs a time-out time to the PID controller 34 at a predetermined time interval to decrease or increase a margin value by an increase or decrease value (Δ).

The margin operator 32 starts to be operated by a control of the PID controller 34, decreases the margin value by the increase or decrease value (Δ) when the PID controller 34 monitors whether the driving deviation (e(t)) has been stabilized in the range of the margin value (margin(t)) and judges that the driving deviation has been stabilized in the range of the margin value to request a margin value decrease operation, and provides the decreased margin value to the PID controller 34.

Here, a margin value initially used by the margin operator 32 may be an initial margin maximum value (margin_max). In this case, the margin operator 32 confirms a state of the stabilizer 33 and performs the operation as described above when a decrease flag is enabled.

Unlike this, the margin operator 32 does not perform an operation of decreasing the margin value when the decrease flag of the stabilizer 33 is disabled.

Meanwhile, the margin operator 32 increases the margin value by the increase or decrease value (Δ) when the PID controller 34 monitors whether the driving deviation has been stabilized in the range of the margin value (margin(t)) and judges that the driving deviation has been out of the range of the margin value to request a margin value increase operation, and provides the increased margin value to the PID controller 34.

Next, the stabilizer 33 includes the decrease flag (decrease flag) and initially maintains the decrease flag in an enabled state by a control of the PID controller 34.

In addition, the stabilizer 33 maintains the decrease flag in this state and then changes the state of the decrease flag into a disabled state when the PID controller 34 monitors whether the driving deviation has been stabilized in the range of the margin value (margin(t)) and judges that the driving deviation has been out of the range of the margin value to request a state change.

When the stabilizer 33 changes the state of the decrease flag into the disabled state, an additional decrease in the margin value in the margin operator 32 is not generated.

The reason why the operation of the stability 33 as described above is required will be described below. When the PID controller 34 performs the automatic gain control while continuously decreasing the margin value, the driving deviation is not in the range of the margin value, but is out of the range of the margin value at any point in time. In this case, after the margin value is increased by the increase or decrease value (Δ), the automatic gain control operation is continued. However, in this case, when an operation of again decreasing the margin value is performed, an operation (Margin(t)−Δ) of decreasing the margin value and an operation to (Margin(t)+Δ) of increasing the margin value are repeated, such that oscillation is generated. The operation of the stabilizer 33 is to prevent the oscillation.

Next, the PID controller 34 controls the timer 31, the margin operator 32, and the stabilizer 33 to start the automatic gain control operation at an initial margin maximum value and perform the automatic gain control operation while decreasing or increasing the margin value, rather than using a fixed margin value.

Next, an operation of the controlling unit according to the preferred embodiment of the present invention will be described in detail with reference to FIG. 2.

When the automatic gain control operation starts, the PID controller 34 sets a driving displacement target value, sets the margin value to the initial margin maximum value, and sets a state of the decrease flag of the stabilizer 33 to the enabled state.

In addition, the PID controller 34 outputs an initial driving signal (Vint) to drive the inertial sensor 1 and then receives the driving displacement output from the displacement measuring unit 20 to continue the automatic gain control operation.

Here, the PID controller 34 starts the automatic gain control operation at a margin value set to the initial margin maximum value (margin_max).

Meanwhile, when the automatic gain control operation starts, the PID controller 34 receives the driving displacement measured by the displacement measuring unit 20 when a time-out signal is output from the timer 31, subtracts the received driving displacement from the target value to calculate the driving deviation, monitors whether the driving deviation has been stabilized in the range of the margin value (margin(t)), and requests a margin value decrease operation to the margin calculator 32 when it is judged that the driving deviation has been stabilized in the range of the margin value for a predetermined time.

When the margin operator 32 receives the request for the margin decrease operation from the PID controller 34, it decreases the initial margin maximum value by the increase or decrease value (Δ) and provides the decreased margin value to the PID controller 34.

In this case, the PID controller 34 continues the automatic gain control operation using the decreased margin value. In addition, the PID controller 34 decreases a magnitude of the driving signal and outputs the driving signal of which the magnitude is decreased.

When the PID controller 34 performs the automatic gain control using the margin value continuously decreased by the margin operator 32 as described above, the case in which the driving deviation is not in the range of the margin value (margin(t)), but is out of the range of the margin value at any point in time occurs.

In this case, the PID controller 34 requests a margin value increase operation to the margin operator 32.

The margin operator 32 receiving the request increases the margin value by the increase or decrease value (Δ) and provides the increased margin value to the PID controller 34.

In this case, the PID controller 34 changes the state of the decrease flag (decrease_flag) of the stabilizer 33 into the disabled state to prevent an additional decrease in the margin value in the margin operator 32.

Therefore, the PID controller 34 continuously performs the automatic gain control using the increased margin value. In this case, the PID controller 34 increases a magnitude of the driving signal.

Meanwhile, when the PID controller 34 performs the automatic gain control using the increased margin value as described above, the driving deviation again enters the range of the margin value. In this case, since the decrease flag of the stabilizer 33 is disabled, the margin operator 32 is no longer operated. Therefore, the PID controller 34 performs a stable operation.

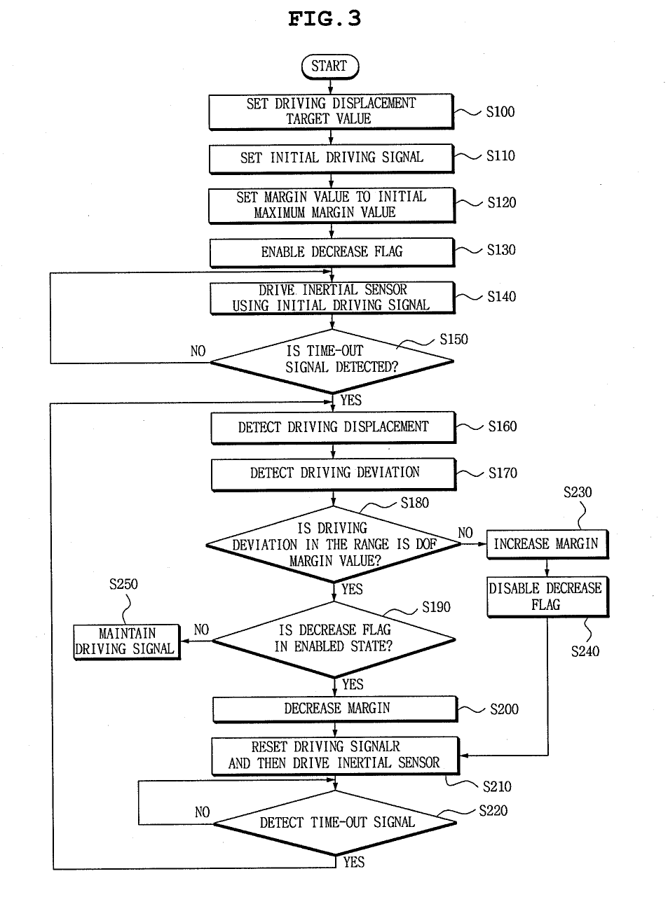

FIG. 3 is a flow chart of an automatic gain control method according to the first preferred embodiment of the present invention.

Referring to FIG. 3, in the automatic gain control method according to the first preferred embodiment of the present invention, when an automatic gain control operation starts, the PID controller sets a driving displacement target value (S100), sets an initial driving signal (S110), and sets a margin value to an initial margin maximum value (S120), and sets a state of a decrease flag of the stabilizer to an enabled state (S130).

Then, the PID controller drives an angular velocity sensor using the initial driving signal (S140), receives a driving displacement output from the displacement measuring unit to detect the driving displacement (S160) when a time-out signal is output from the timer (S150).

Thereafter, the PID controller subtracts the target value from the driving displacement to detect a driving deviation (S170) and judges whether the driving deviation is in the range of the margin value (S180).

When it is judged that the driving deviation is in the range of the margin value, the PID controller requests a margin value decrease to the margin operator to decrease the margin value. In this case, the margin operator confirms a state of the decrease flag and subtracts an increase or decrease value from the initial margin maximum value, which is the previous margin value, to decrease the margin (S200) when the decrease flag is in the enabled state (S190). Next, after the driving signal is reset (after a magnitude of the driving signal is decreased), the inertial sensor is driven (S210).

Then, the PID controller judges whether the time-out signal has been output from the timer (S220), and a process after the step (S160) is repeated when it is judged that the time-out signal has been output from the timer.

Meanwhile, when the driving deviation is out of the range of the margin value, the PID controller requests a margin value increase to the margin operator to increase the margin (S230) and then disables the decrease flag of the stabilizer (S240).

Then, the PID controller resets the driving signal and then drives the inertial sensor (S210).

Next, the PID controller judges whether the time-out signal has been output from the timer, and a process after the step (S160) is repeated when it is judged that the time-out signal has been output from the timer.

As described above, according to the preferred embodiment of the present invention, at the time of the automatic gain control operation, the margin value is not fixed, but is changed according to a situation change to minimize the driving deviation value of the automatic gain control, thereby making it possible to more precisely perform a control.

Meanwhile, referring to FIGS. 2 and 3, the controlling unit according to the preferred embodiment of the present invention has reset and used the driving signal while decreasing the margin value from the initial margin maximum value by a predetermined value.

However, in the case of the first preferred embodiment of the present invention as described above, when the increase or decrease value (Δ) of the margin value is excessively large, the driving deviation becomes excessively large. The reason is that the driving deviation may be generated up to the maximum margin value.

Unlike this, when the increase or decrease value (Δ) of the margin value is excessively small, the driving deviation may be minimized; however, a large number of operations should be repeated in order for the margin value to approach the most efficient solution. That is, a lock time of the automatic gain control is increased.

Therefore, in a second preferred embodiment of the present invention, the controlling unit 30 controls the margin value by a statistical approach method to minimize the driving deviation.

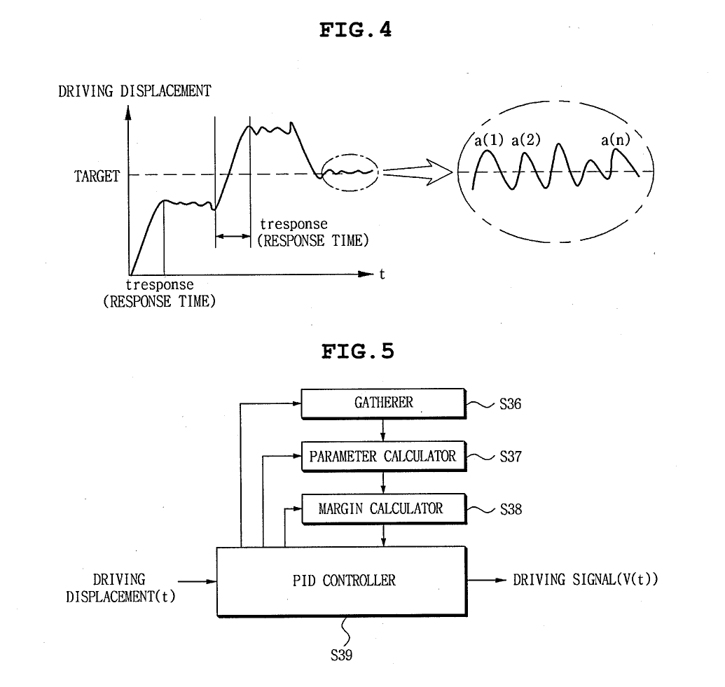

To this end, when the driving displacement (t) is stabilized after a response time tresponse elapses after the initial driving signal is applied as shown in FIG. 4, the controlling unit gathers amplitude values (a(1), a(2), . . . , a(n)) of the driving displacement in each period for a predetermined time. Here, the gathered amplitude values of the driving displacement in each period are called observed values.

Then, the controlling unit 30 extracts a statistical parameter. Here, an example of the used statistical parameter includes an average (See the following Equation 1) of the observed values, a deviation (See the following Equation 2) of the observed values, a deviation maximum value (See the following Equation 3) of the observed values, a variance (See the following Equation 4) of the observed values, a standard deviation (See the following Equation 5) of the observed values, and the like.

$$\begin{matrix}Average ( xavg ) of observed values = avg ( a ( 1 ) , a ( 2 ) , ⋯ , a ( n ) ) & ( Equation 1 ) \\ Deviation of observed values = \vert observed \text{value-average} \vert & ( Equation 2 ) \\ Deviation maximum value of observed values = max \vert observed \text{value-average} \vert & ( Equation 3 ) \\ Variance ( v ) of observed values = \vert \frac{{\sum }_{i = 1}^{n} ( a ( i ) - \text{?}}{n} & ( Equation 4 ) \\ Standard deviation ( s ) of observed values = \vert \sqrt{V} \\ \text{?} \text{indicates text missing or illegible when filed} & ( Equation 5 )\end{matrix}$$

When the statistical parameter is extracted as described above, the controlling unit 30 set the margin value using the extracted parameter. When the margin value is set, a weight may be used.

As an example, the controlling unit 30 may use the deviation maximum value as the margin value or use a value obtained by multiplying the deviation maximum value by the weight as the margin value.

In addition, the controlling unit 30 may use the standard deviation as the margin value or use a value obtained by multiplying the standard deviation by the weight as the margin value.

Further, the controlling unit 30 calculates the driving deviation by subtracting the target value from the driving displacement detected by the displacement detecting unit 20 to judge whether the driving deviation is in the range of the margin value.

The controlling unit 30 resets the driving signal (controls a magnitude of the driving signal) when the driving deviation is out of the range of the margin value and then drives the inertial sensor.

In addition, when the driving displacement (t) is stabilized after the response time tresponse elapses after the driving signal is applied as shown in FIG. 4, the controlling unit again gathers amplitude values of the driving displacement for a predetermined time. Here, the gathered amplitude values are called observed values.

Then, the controlling unit 30 extracts the statistical parameter such as the average of the observed values, the deviation of the observed values, the deviation maximum value of the observed values, the variance of the observed values, the standard deviation of the observed values, and the like and sets the margin value using the extracted parameter. When the margin value is set, a weight may be used.

Further, the controlling unit 30 calculates the driving deviation by subtracting the target value from the driving displacement detected by the displacement detecting unit 20 to again judge whether the driving deviation is in the range of the margin value and repeats the above-mentioned process when it is judged that the driving deviation is not in the range of the margin value.

Unlike this, the controlling unit 30 judges that the driving deviation detected by the displacement detecting unit 20 has been stabilized when the driving deviation is in the range of the margin value to maintain a state of the driving deviation.

FIG. 5 is a configuration diagram of a controlling unit of FIG. 1 according to a second preferred embodiment of the present invention.

Referring to FIG. 5, the controlling unit of FIG. 1 according to the second preferred embodiment of the present invention includes a gatherer 36, a parameter calculator 37, a margin calculator 38, and a PID controller 39.

When the PID controller 39 informs the gatherer 36 that a response time according to a driving signal elapses, the gatherer 36 gathers amplitude values of a driving displacement in each period to configure observed values.

The operation of the gatherer 36 described above is continued for a predetermined set time.

Meanwhile, the parameter calculator 37 statistically calculates and outputs an average, a deviation, a deviation maximum value, a variance, a standard deviation, and the like, of the observed values gathered by the gatherer 36.

In addition, the margin calculator 38 sets a margin value using the parameter value calculated by the parameter calculator 37. In this case, the margin calculator 38 calculates and outputs the margin value by allocating a weight.

Meanwhile, the PID controller 39 drives the inertial sensor using an initial driving signal to allow the gatherer 36 to gather the observed values, allow the parameter calculator 37 to calculate the parameter, and then allow the margin calculator 38 to calculate the margin value. When the driving deviation is larger than the calculated margin value, the PID controller 39 resets the driving signal to drive the inertial sensor and then allow the above-mentioned process to be repeated.

Next, an operation of the controlling unit shown in FIG. 5 will be described below in detail.

First, the PID controller applies the initial driving signal to the inertial sensor as shown in FIG. 4.

Then, the HD controller allows the gatherer 36 to gather the amplitude values of the driving displacement t in each period when a response time tresponse according to the initial driving signal elapses. Here, the gathered amplitude values of the driving displacement in each period are called observed values.

Thereafter, the parameter calculator 37 extracts the statistical parameter. Here, an example of the used statistical parameter includes the average of the observed values, the deviation of the observed values, the deviation maximum value of the observed values, the variance of the observed values, the standard deviation of the observed values, and the like.

When the parameter calculator 37 extracts the statistical parameter as described above, the margin calculator 38 may set the margin value using the extracted parameter and set the margin value using a weight.

Then, the PID controller 39 calculates the driving deviation by subtracting the target value from the driving displacement detected by the displacement detecting unit 20 to judge whether the driving deviation is in the range of the margin value.

The PID controller 39 resets the driving signal (that is, resets a magnitude of the driving signal) when the driving deviation is out of the range of the margin value and then drives the inertial sensor.

Then, when the driving displacement (t) is stabilized after the response time tresponse elapses after the driving signal is applied as shown in FIG. 4, the PID controller 39 again gathers amplitude values of the driving displacement in each period for a predetermined time using the gatherer 36. Here, the gathered amplitude values of the driving displacement in each period are called observed values.

Thereafter, the PID controller 39 extracts the statistical parameter. Here, an example of the used statistical parameter includes the average of the observed values, the deviation of the observed values, the deviation maximum value of the observed values, the variance of the observed values, the standard deviation of the observed values, and the like.

When the statistical parameter is extracted as described above, the PID controller sets the margin value using the extracted statistical parameter. When the margin value is set, a weight may be used.

Further, the PID controller 39 calculates the driving deviation by subtracting the target value from the driving displacement detected by the displacement detecting unit 20 to judge whether the driving deviation is in the range of the margin value and repeats the above-mentioned process when it is judged that the driving deviation is not in the range of the margin value.

Unlike this, the PID controller 39 judges that the driving deviation detected by the displacement detecting unit 20 has been stabilized when the driving deviation is in the range of the margin value to maintain a state of the driving deviation.

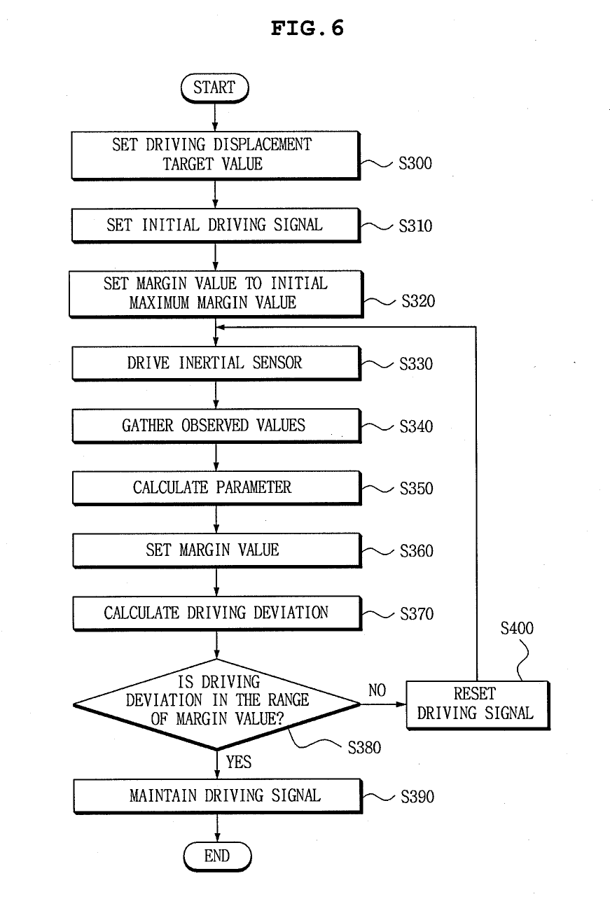

FIG. 6 is a flow chart of an automatic gain control method according to the second preferred embodiment of the present invention.

Referring to FIG. 6, in the automatic gain control method according to the second preferred embodiment of the present invention, when an automatic gain control operation starts, the HD controller of the controlling unit sets a driving displacement target value (S300), sets a driving signal to an initial driving signal (Vint) (S310), and sets a margin value to an initial margin maximum value (S320).

Then, the PID controller of the controlling unit applies the initial driving signal to the inertial sensor as shown in FIG. 4 (S330).

Then, the PID controller of the controlling unit controls the gatherer to gather amplitude values of a driving displacement t in each period when a response time tresponse according to the initial driving signal elapses (S340). Here, the gathered amplitude values of the driving displacement in each period are called observed values.

Thereafter, the parameter calculator of the controlling unit extracts statistical parameter (S350). Here, an example of the used statistical parameter includes the average of the observed values, the deviation of the observed values, the deviation maximum value of the observed values, the variance of the observed values, the standard deviation of the observed values, and the like.

When the parameter calculator extracts the statistical parameter as described above, the margin calculator of the controlling unit may set the margin value using the extracted parameter or set the margin value using a weight (S360).

As an example, the margin calculator of the controlling unit may use the deviation maximum value as the margin value or use a value obtained by multiplying the deviation maximum value by the weight as the margin value.

In addition, the margin calculator of the controlling unit may use the standard deviation as the margin value or use a value obtained by multiplying the standard deviation by the weight as the margin value.

Then, the PID controller of the controlling unit calculates a driving deviation by subtracting the target value from the driving displacement detected by the displacement detecting unit (S370) and judges whether the driving deviation is in the range of the margin value (S380).

The PID controller resets the driving signal (that is, resets a magnitude of the driving signal) (S400) when it is judged that the driving deviation is not in the range of the margin value and drives the inertial sensor, thereby repeating the subsequent operations.

Meanwhile, the PID controller maintains the driving signal (S390) when the driving deviation is in the range of the margin value.

According to the preferred embodiment of the present invention as described above, the margin value is rapidly calculated by the statistical approach method, thereby making it possible to more precisely control the driving deviation of the automatic gain control.

In addition, according to the preferred embodiment of the present invention, a lock time of the automatic gain control is minimized, thereby making it possible to decrease a calculation amount and power consumption.

Further, according to the preferred embodiment of the present invention, the driving deviation of the inertial sensor is decreased by a precise automatic gain control operation, thereby making it possible to improve accuracy of the inertial sensor.

According to the preferred embodiment of the present invention, at the time of the automatic gain control operation, the margin value is not fixed, but is changed according to a situation change to minimize the driving deviation of the automatic gain control, thereby making it possible to more precisely perform a control.

As a result, the driving deviation of the inertial sensor is decreased by a precise automatic gain control operation, thereby making it possible to improve accuracy of the inertial sensor.

In addition, according to the preferred embodiment of the present invention as described above, the margin value is rapidly calculated by the statistical approach method, thereby making it possible to minimize and more precisely control the driving deviation of the automatic gain control.

Further, according to the preferred embodiment of the present invention, a lock time of the automatic gain control is minimized, thereby making it possible to decrease a calculation amount and power consumption.

Furthermore, according to the preferred embodiment of the present invention, the driving deviation of the inertial sensor is decreased by a precise automatic gain control operation, thereby making it possible to improve accuracy of the inertial sensor.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. An adaptive automatic gain control apparatus for an inertial sensor, comprising:
a displacement measuring unit measuring and outputting a driving displacement of the inertial sensor; and
a controlling unit driving the inertial sensor using an initial driving signal and then resetting a driving signal while changing a margin value using the driving displacement measured by the displacement measuring unit, thereby driving the inertial sensor.

2. The adaptive automatic gain control apparatus for an inertial sensor as set forth in claim 1, further comprising a low pass filter filtering noise from the driving displacement measured by the displacement measuring unit to provide the driving displacement from which the noise is filtered to the controlling unit.

3. The adaptive automatic gain control apparatus for an inertial sensor as set forth in claim 1, wherein the controlling unit drives the inertial sensor using the initial driving signal, calculates a driving deviation by subtracting the driving displacement measured by the displacement measuring unit from a driving displacement target value after a predetermined time elapses, and resets the driving signal while decreasing the margin value when the calculated driving deviation is in the range of an initial maximum margin value, thereby driving the inertial sensor.

4. The adaptive automatic gain control apparatus for an inertial sensor as set forth in claim 3, wherein the controlling unit drives the inertial sensor using the reset driving signal and resets the driving signal while decreasing the margin value when the driving deviation is in the range of the previous margin value after a predetermined time elapses, thereby driving the inertial sensor.

5. The adaptive automatic gain control apparatus for an inertial sensor as set forth in claim 3, wherein the controlling unit drives the inertial sensor using the reset driving signal and resets the driving signal while increasing the margin value when the driving deviation is out of the range of the previous margin value after a predetermined time elapses, thereby driving the inertial sensor.

6. The adaptive automatic gain control apparatus for an inertial sensor as set forth in claim 4, wherein the controlling unit maintains the driving signal when the driving deviation again enters the range of the margin value.

7. The adaptive automatic gain control apparatus for an inertial sensor as set forth in claim 3, wherein the controlling unit includes:
a timer outputting a time-out signal at a predetermined time interval;
a margin calculator subtracting or adding an increase or decrease value from or to the previous margin value to output an adjusted margin value; and
a proportional integral derivative (PID) controller drives the inertial sensor using the initial driving signal, calculates the driving deviation by subtracting the driving displacement measured by the displacement measuring unit from the driving displacement target value when the time-out signal is output from the timer, requests the margin calculator to decrease the margin value when the calculated driving deviation is in the range of the initial maximum margin value, and receives the decreased margin value to reset the driving signal, thereby driving the inertial sensor.

8. The adaptive automatic gain control apparatus for an inertial sensor as set forth in claim 7, wherein the PID controller drives the inertial sensor using the reset driving signal, calculates the driving deviation by subtracting the driving displacement measured by the displacement measuring unit from the driving displacement target value when the time-out signal is output from the timer, requests the margin calculator to decrease the margin value when the driving deviation is in the range of the previous margin value, and receives the decreased margin value to reset the driving signal, thereby driving the inertial sensor.

9. The adaptive automatic gain control apparatus for an inertial sensor as set forth in claim 8, wherein the controlling unit further includes a stabilizer having a decrease flag, maintained in an enabled state when the driving deviation is in the range of the previous margin value, and maintained in a disabled state when the driving deviation is out of the range of the previous margin value,
wherein the PID controller drives the inertial sensor using the reset driving signal, calculates the driving deviation by subtracting the driving displacement measured by the displacement measuring unit from the driving displacement target value when the time-out signal is output from the timer, changes a state of the stabilizer into the disabled state and requests the margin calculator to increase the margin value when the driving deviation is out of the range of the margin value, and receives the increased margin value to reset the driving signal, thereby driving the inertial sensor.

10. The adaptive automatic gain control apparatus for an inertial sensor as set forth in claim 9, wherein the PID controller calculates the driving deviation by subtracting the driving displacement measured by the displacement measuring unit from the driving displacement target value when the time-out signal is output from the timer and requests the margin calculator to decrease the margin value when the driving deviation again enters the range of the margin value,
the margin calculator confirms a state of the stabilizer and outputs the previous margin value to the PID controller when the stabilizer is in the disabled state, and
the PID controller maintains the driving signal when the previous margin value is output from the margin calculator.

11. The adaptive automatic gain control apparatus for an inertial sensor as set forth in claim 1, wherein the controlling unit drives the inertial sensor using the initial driving signal, gathers amplitudes of the driving displacement in each of a plurality of periods measured by the displacement measuring unit as observed values to calculate a parameter after a predetermined time elapses, sets the margin value using the parameter, calculates a driving deviation by subtracting the driving displacement measured by the displacement measuring unit from a driving displacement target value, and resets the driving signal when the calculated driving deviation is out of the range of the set margin value, thereby driving the inertial sensor.

12. The adaptive automatic gain control apparatus for an inertial sensor as set forth in claim 11, wherein the controlling unit drives the inertial sensor using the reset driving signal, gathers the amplitudes of the driving displacement in each of the plurality of periods measured by the displacement measuring unit as the observed values to calculate the parameter after a predetermined time elapses, sets the margin value using the parameter, calculates the driving deviation by subtracting the driving displacement measured by the displacement measuring unit from the driving displacement target value, and resets the driving signal when the calculated driving deviation is out of the range of the set margin value, thereby driving the inertial sensor.

13. The adaptive automatic gain control apparatus for an inertial sensor as set forth in claim 12, wherein the controlling unit drives the inertial sensor using the reset driving signal, gathers the amplitudes of the driving displacement in each of the plurality of periods measured by the displacement measuring unit as the observed values to calculate the parameter after the predetermined time elapses, sets the margin value using the parameter, calculates the driving deviation by subtracting the driving displacement measured by the displacement measuring unit from the driving displacement target value, and maintains the driving signal when the calculated driving deviation is in the range of the set margin value, thereby driving the inertial sensor.

14. The adaptive automatic gain control apparatus for an inertial sensor as set forth in claim 11, wherein the parameter is at least one of an average of the observed values, a deviation of the observed values, a deviation maximum value of the observed values, a variance of the observed values, and a standard deviation of the observed values.

15. The adaptive automatic gain control apparatus for an inertial sensor as set forth in claim 11, wherein the controlling unit includes:
a gatherer gathering the amplitudes of the driving displacement in each of the plurality of periods measured by the displacement measuring unit as the observed values;
a parameter calculator calculating the parameter using the observed values gathered by the gatherer;
a margin calculator setting the margin value using the parameter calculated by the parameter calculator; and
a PID controller drives the inertial sensor using the initial driving signal, sets the margin value using the gatherer, the parameter calculator, and the margin calculator, calculates the driving deviation by subtracting the driving displacement measured by the displacement measuring unit from the driving displacement target value, and resets the driving signal when the calculated driving deviation is out of the range of the set margin value, thereby driving the inertial sensor.

16. The adaptive automatic gain control apparatus for an inertial sensor as set forth in claim 15, wherein the PID controller drives the inertial sensor using the reset driving signal, sets the margin value using the gatherer, the parameter calculator, and the margin calculator, calculates the driving deviation by subtracting the driving displacement measured by the displacement measuring unit from the driving displacement target value, and resets the driving signal when the calculated driving deviation is out of the range of the set margin value, thereby driving the inertial sensor.

17. The adaptive automatic gain control apparatus for an inertial sensor as set forth in claim 15, wherein the PID controller drives the inertial sensor using the reset driving signal, sets the margin value using the gatherer, the parameter calculator, and the margin calculator, calculates the driving deviation by subtracting the driving displacement measured by the displacement measuring unit from the driving displacement target value, and maintains the driving signal when the calculated driving deviation is in the range of the set margin value, thereby driving the inertial sensor.

18. An adaptive automatic gain control method for an inertial sensor, comprising:
(A) driving, by a controlling unit, the inertial sensor using an initial driving signal;
(B) outputting, by a displacement measuring unit, measuring and outputting a driving displacement of the inertial sensor after a predetermined time elapses; and
(C) resetting, by the controlling unit, the driving signal while changing a margin value using the driving displacement measured by the displacement measuring unit, thereby driving the inertial sensor.

19. The adaptive automatic gain control method for an inertial sensor as set forth in claim 18, further comprising, after the step (B), (D) filtering, by a low pass filter, noise from the driving displacement measured by the displacement measuring unit to provide the driving displacement from which the noise is filtered to the controlling unit.

20. The adaptive automatic gain control method for an inertial sensor as set forth in claim 18, wherein the step (C) includes:
(C-1) calculating, by the controlling unit, a driving deviation by subtracting the driving displacement measured by the displacement measuring unit from a driving displacement target value; and
(C-2) resetting, by the controlling unit, the driving signal while decreasing the margin value when the calculated driving deviation is in the range of an initial maximum margin value, thereby driving the inertial sensor.

21. The adaptive automatic gain control method for an inertial sensor as set forth in claim 20, further comprising:
(E) driving, by the controlling unit, the inertial sensor using the reset driving signal;
(F) measuring and outputting, by the displacement measuring unit, the driving displacement of the inertial sensor after the predetermined time elapses;
(G) calculating, by the controlling unit, the driving deviation by subtracting the driving displacement measured by the displacement measuring unit from the driving displacement target value; and
(H) resetting, by the controlling unit, the driving signal while decreasing the margin value when the calculated driving deviation is in the range of the previous margin value, thereby driving the inertial sensor.

22. The adaptive automatic gain control method for an inertial sensor as set forth in claim 21, further comprising (I) resetting the driving signal while increasing the margin value when the driving deviation calculated in the step (G) is out of the range of the previous margin value, thereby driving the inertial sensor.

23. The adaptive automatic gain control method for an inertial sensor as set forth in claim 22, further comprising:
(J) driving, by the controlling unit, the inertial sensor using the reset driving signal;
(K) measuring and outputting, by the displacement measuring unit, the driving displacement of the inertial sensor after the predetermined time elapses;
(L) calculating, by the controlling unit, the driving deviation by subtracting the driving displacement measured by the displacement measuring unit from the driving displacement target value; and
(M) maintaining, by the controlling unit, the driving signal when the driving deviation again enters the range of the margin value, thereby driving the inertial sensor.

24. The adaptive automatic gain control method for an inertial sensor as set forth in claim 18, wherein the step (C) includes:
(C-1) gathering, by the controlling unit, amplitudes of the driving displacement in each of a plurality of periods measured by the displacement measuring unit as observed values to calculate a parameter and setting the margin value using the parameter; and
(C-2) calculating, by the controlling unit, a driving deviation by subtracting the driving displacement measured by the displacement measuring unit from a driving displacement target value, and resetting the driving signal when the calculated driving deviation is out of the range of the set margin value, thereby driving the inertial sensor.

25. The adaptive automatic gain control method for an inertial sensor as set forth in claim 24, further comprising:
(N) driving, by the controlling unit, the inertial sensor using the reset driving signal;
(O) measuring and outputting, by the displacement measuring unit, the driving displacement after a predetermined time elapses;
(P) gathering, by the controlling unit, the amplitudes of the driving displacement in each of the plurality of periods measured by the displacement measuring unit as the observed values to calculate the parameter and setting the margin value using the parameter;
(Q) calculating, by the controlling unit, the driving deviation by subtracting the driving displacement measured by the displacement measuring unit from the driving displacement target value; and
(R) resetting, by the controlling unit, the driving signal when the calculated driving deviation is out of the range of the set margin value, thereby driving the inertial sensor.

26. The adaptive automatic gain control method for an inertial sensor as set forth in claim 25, further comprising, (S) maintaining, by the controlling unit, the driving signal when the driving deviation calculated in the step (Q) is in the range of the set margin value, thereby driving the inertial sensor.

27. The adaptive automatic gain control method for an inertial sensor as set forth in claim 24, wherein the parameter is at least one of an average of the observed values, a deviation of the to observed values, a deviation maximum value of the observed values, a variance of the observed values, and a standard deviation of the observed values.
